(19) United States
(12) Patent Application Publication
(10) Pub. No.: US 2010/0090229 A1
(43) Pub. Date: Apr. 15, 2010

(54) SEMICONDUCTOR LIGHT EMITTING APPARATUS AND METHOD FOR PRODUCING THE SAME

(76) Inventor: Mitsunori HARADA, Tokyo (JP)

Correspondence Address: CERMAK KENEALY VAIDYA & NAKAJIMA LLP, 515 EAST BRADDOCK RD SUITE B, Alexandria, VA, 22314, US

(21) Appl. No.: 12/577,714

(22) Filed: Oct. 12, 2009

(30) Foreign Application Priority Data
Oct. 10, 2008 (JP) 2008-264439

(51) Int. Cl. H01L 33/00

(52) U.S. Cl. 257/88; 438/27; 438/28; 257/E33.056; 257/E33.067

(57) ABSTRACT

A light emitting apparatus can have a front luminous intensity distribution having a sharp difference at the interface between the light emitting area and the surrounding non-light emitting area (outer environment) so as to suppress or prevent light color unevenness. The semiconductor light emitting apparatus can include a substrate, a plurality of light emitting elements each having a top surface as a light emitting surface and disposed on the substrate with a predetermined gap between the adjacent light emitting elements, bridge portions each disposed at the gap between the adjacent light emitting elements so as to connect the light emitting elements, and a wavelength conversion layer disposed over the top surfaces of the plurality of the light emitting elements and the bridge portions entirely. The wavelength conversion layer can have a decreased thickness at least around its peripheral area and gradually tapering to its end portion.

This application claims the priority benefit under 35 U.S.C. §119 of Japanese Patent Application No. 2008-264439 filed on Oct. 10, 2008, which is hereby incorporated in its entirety by reference.

### TECHNICAL FIELD

The presently disclosed subject matter relates to a semiconductor light emitting apparatus including a plurality of semiconductor light emitting devices, and in particular, to a semiconductor light emitting apparatus including a wavelength conversion layer containing a phosphor material or the like.

### BACKGROUND ART

Based on recent developments in the area of high-powered and high-intensity light emitting diodes (LEDs), white LEDs have gradually been used as light sources for vehicle headlights, general lighting fixtures, street lamps, traffic lamps, and various illumination apparatuses. Such a white LED can include, for example, a blue LED and a wavelength conversion layer containing a phosphor material or the like. The blue LED can emit blue light, and part of the blue light is wavelength converted by the wavelength conversion material in the wavelength conversion layer to become yellow light (or yellowish orange light). This yellow light is mixed with the original blue light so that white light is obtained.

Known methods for forming a phosphor-containing layer which covers over the side and/or top surfaces of an LED chip include a stencil printing method, a screen printing method using a metal mask, a suspension coating method and other methods, for example, disclosed in Japanese Patent Application Laid-Open Nos. 2002-185048, 2006-313886, and 2003-526212, respectively. Furthermore, Japanese Patent Application Laid-Open No. 2001-244507 discloses a structure in which a phosphor layer is formed only on the top surface of an LED chip by a gas-phase growth method such as a vapor deposition method, a sputtering method, or the like. Japanese Patent Application Laid-Open No. 2005-109434 discloses a structure in which two light emitting elements are arranged side by side between which a resin is filled, and a wavelength conversion member is formed by a screen printing method or a stencil printing method so as to cover the entire top surface of the two light emitting elements.

### SUMMARY

Some illumination apparatuses, such as vehicle headlights, may be required to have a front luminous intensity distribution having a sharp difference at the interface between the light emitting area and the surrounding non-light emitting area (outer environment). When a white LED is used as a light source for such an illumination apparatus, the LED should have a configuration that can emit light from the top surface of the LED in the front direction with high directivity while the light emitted in the oblique or horizontal directions should be prevented.

The LEDs as disclosed in Japanese Patent Application Laid-Open Nos. 2002-185048, 2006-313886, and 2003-526212 include a phosphor-containing layer that covers the side and top faces of the LED chip. In this configuration, the light can be emitted not only from the top surface of LED in the front direction but also from the side faces thereof in the horizontal or obliquely downward directions. Some of such light can be reflected by the substrate or other members to be directed in the front direction. Accordingly, the front luminous intensity distribution may have a gradually decreased distribution near the periphery of the LED. The LEDs as disclosed in Japanese Patent Application Laid-Open Nos. 2001-244507 and 2005-109434 have the phosphor-containing resin layer provided on the top surface thereof, and the layer has a rectangular end surface perpendicular to the top surface. In this configuration, light can be emitted from the end surface of the phosphor-containing resin layer in the horizontal or obliquely downward directions, and then can be directed in the front direction by the reflection from the substrate or other members. Accordingly, this configuration also provides a front luminous intensity distribution having a gradually decreased distribution near the periphery of the LED.

Furthermore, when a plurality of LED chips are to be arrayed in line to form a single LED light emitting apparatus, the formation of the phosphor-containing layer on the individual LED chip by printing or similar methods as disclosed in Japanese Patent Application Laid-Open Nos. 2002-185048, 2006-313886, 2003-526212 and 2001-244507 may have the following problems. That is, the phosphor-containing layer may have a distribution unevenness of the contained phosphor particles, resulting in light color unevenness of the arrayed LED light emitting apparatuses. This may be caused by the local light intensity decrease between the adjacent LED chips.

The presently disclosed subject matter was devised in view of these and other issues, characteristics and problems and in association with the conventional art. According to one aspect of the presently disclosed subject matter, a light emitting apparatus can include a plurality of light emitting elements arranged in an array and a wavelength conversion layer configured to wavelength convert part of light emitted from the light emitting elements. The light emitting apparatus can have a front luminous intensity distribution having a sharp difference at the interface between a light emitting area and a surrounding non-light emitting area (outer environment) so as to suppress or prevent light color unevenness.

According to another aspect of the presently disclosed subject matter, a semiconductor light emitting apparatus can include: a substrate; a plurality of light emitting elements each having a top surface as a light emitting surface and disposed on the substrate with a predetermined gap interposed between the adjacent light emitting elements; bridge portions each disposed at the respective gaps between the adjacent light emitting elements so as to connect the light emitting elements; and a wavelength conversion layer disposed over the top surfaces of the plurality of the light emitting elements and the bridge portions entirely. The wavelength conversion layer can have a thickness that is decreased at least around its peripheral area and can be gradually thinned to the end portion. The thickness of the wavelength conversion layer covering the elements and the like entirely can be decreased toward the end portion, and accordingly, the light emitted horizontally or toward the substrate from the wavelength conversion layer can be reduced. In addition to this, the wavelength conversion layer covering the plurality of the light emitting elements as a unit can reduce the occurrence of the light color unevenness.

In the above configuration, the wavelength conversion layer can have a top surface to be formed as a convex curved surface in the front direction. This configuration can flatten the luminous intensity distribution at the positions of the LED elements, thereby reducing the luminous intensity unevenness.

In the above configuration, the wavelength conversion layer can be devoid of an end surface that is substantially perpendicular to the main plane including the top surface. For example, all surfaces of the wavelength conversion layer that are exposed away from the light emitting element and that ultimately end and are in contact with the light emitting element can extend from a plane containing the top surface of the light emitting element at an angle other than substantially ninety degrees.

The wavelength conversion layer can include a wavelength conversion material and a resin containing the wavelength conversion material dispersed therein (for example, a resin to which phosphor particles are added and dispersed).

The bridge portion can have a width and a length that are equal to or more than the size of the gap between the adjacent light emitting elements, and can have longitudinal ends that are disposed on the same plane as the top surface of the light emitting element. This configuration can maintain, even at the bridge portion, the surface tension of the mixed liquid material that serves as the wavelength conversion layer after it has been dropped onto the light emitting element and the bridge portion. The maintained surface tension can ensure the correct configuration for the wavelength conversion layer when it is coated over the entire surface of the plurality of light emitting elements. The bridge portion, for example, can also be described as having longitudinal ends that are the outermost peripheral portion of the bridge portion (when viewed in a light emitting direction of the apparatus) and that lie within a plane containing the top surface of the light emitting element(s).

In this configuration, the bridge portion and the substrate can form a space therebetween, with the space being vacant. This configuration can help the ends of the bridge portion to be disposed on the same plane as the top surface of the light emitting element.

The bridge portion can have a shape having inclined surfaces from its apex toward the top surface of the light emitting element along the longitudinal direction of the gap. The inclined surfaces of the bridge portion can reflect the light from the light emitting element so that the reflected light can be directed in the front direction (upward), thereby increasing the luminous intensity.

In the above configuration, the bridge portion can be composed of a filler having a light reflecting property and a resin containing the filler therein.

According to still another aspect of the presently disclosed subject matter, a method for producing such a semiconductor light emitting apparatus can include: disposing a plurality of light emitting elements, each having a top surface as a light emitting surface, on a substrate with a predetermined gap interposed between the adjacent light emitting elements; disposing bridge portions at the gaps between the adjacent light emitting elements; and forming a wavelength conversion layer disposed over the top surfaces of the plurality of the light emitting elements and the bridge portions entirely, wherein the wavelength conversion layer can have a thickness decreased at least around a peripheral area thereof and gradually thinned to an end portion thereof.

The act of forming the wavelength conversion layer can include, for example, a step of dropping a material mixed liquid for the wavelength conversion layer onto the bridge portions and the plurality of the light emitting elements to form a coating film over the entire surfaces of the bridge portions and the light emitting elements with the coating film being convex maintained by its surface tension, and curing the coating film.

The act of disposing the bridge portions can include disposing the bridge portions each having a width and a length that are equal to or more than the size of the gap between the adjacent light emitting elements, so that longitudinal ends of the bridge portions are disposed on the same plane as the top surface of the light emitting element.

For example, the act of disposing the bridge portions can be achieved by extruding a thixotropic resin material from a nozzle with a predetermined opening diameter so as to fill the gap between the light emitting elements therewith, and curing the material.

The act of disposing the bridge portions can include the steps of extruding a thixotropic resin material from a nozzle with a predetermined opening diameter so as to form the resin material disposed at the gap between the light emitting elements, with the extruded material having inclined surfaces from its apex toward the top surface of the light emitting element along the longitudinal direction of the gap, and curing the resin material.

The act of disposing the bridge portions also can include disposing the thixotropic resin material only above the gap between the adjacent light emitting elements so as to form a vacant space between the substrate and the bridge portion. This configuration can help the ends of the bridge portion to be disposed on the same plane as the top surface of the light emitting element with ease.

The method can include, before forming the wavelength conversion layer, connecting electrodes formed on the light emitting elements to wirings formed on the substrate by wire bonding. As the wire bonding operation is performed before the material for the wavelength conversion layer adheres to the electrodes, the electrical reliability can be improved.

According to the presently disclosed subject matter, there can be provided a semiconductor light emitting apparatus including a plurality of light emitting elements arranged in array and a wavelength conversion layer for wavelength converting part of the light emitted from the light emitting elements, thereby providing a front luminous intensity distribution having a sharp difference at the interface between the light emitting area and the surrounding non-light emitting area (outer environment) as well as the suppressed light color unevenness.

### BRIEF DESCRIPTION OF DRAWINGS

These and other characteristics, features, and advantages of the presently disclosed subject matter will become clear from the following description with reference to the accompanying drawings, wherein:

FIG. 1A is a top plan view of a semiconductor light emitting apparatus of a first exemplary embodiment made in accordance with principles of the presently disclosed subject matter, FIG. 1B is a side view of the semiconductor light emitting apparatus of FIG. 1A, and FIG. 1C is a diagram illustrating the bridge portion showing the case where it is just coated (as a perspective view) and the case where it is cured (as a side view);

FIG. 2A is a cross sectional view taken along line A-A′ in FIG. 1A, illustrating a process in the method for producing the semiconductor light emitting apparatus of the first exemplary embodiment showing the case just after the coating film of the wavelength conversion layer material is formed, and FIG. 2B is a cross sectional view taken along line A-A′ in FIG. 1A, illustrating the semiconductor light emitting apparatus of the first exemplary embodiment showing the case where the coating film is cured to form the wavelength conversion layer;

FIG. 3A includes diagrams illustrating the bridge portion of FIG. 1 formed by coating a resin material in a cylindrical shape, shaping the ends thereof to be rounded, and then curing the resin material, FIG. 3B includes diagrams illustrating another embodiment of the bridge portion of FIG. 1 formed by coating a resin material in a elliptic cylindrical shape, shaping the ends thereof to be rounded, and then curing the resin material, and FIG. 3C includes diagrams illustrating still another embodiment of the bridge portion formed in a triangular prism shape;

FIG. 4A is a cross sectional view illustrating a process in a method for producing a conventional semiconductor light emitting apparatus, showing the case, when the ends of the bridge portion 9105 are located below the top surface of the light emitting element, the material for the wavelength conversion layer being dropped onto the top surface of the light emitting element, and FIG. 4B is a cross sectional view illustrating the case where the dropped material for the wavelength conversion material has run off from the ends of the bridge portion;

FIG. 5 is a cross sectional view of a light emitting element 102 of the semiconductor light emitting apparatus of FIG. 1A;

FIGS. 6A, 6B, and 6C are each top plan views and side views of the semiconductor light emitting apparatus of the first exemplary embodiment in the respective producing method;

FIG. 7A is a top plan view of a semiconductor light emitting apparatus of a second exemplary embodiment made in accordance with principles of the presently disclosed subject matter, FIG. 7B is a side view of the semiconductor light emitting apparatus, and FIG. 7C includes perspective views of the bridge portion just after coating and just after leveling before curing;

FIG. 8 is a side view of a semiconductor light emitting apparatus of a third exemplary embodiment made in accordance with principles of the presently disclosed subject matter;

FIG. 9A is a side view illustrating the bridge portion that has been separately produced for use in the present exemplary embodiment, FIG. 9B includes a perspective view and a cross sectional view illustrating another embodiment of the separately produced bridge portion in the form of a quadratic prism, parallelepiped prism or a rectangular prism, FIG. 9C includes a perspective view and a cross sectional view illustrating still another embodiment of the separately produced bridge portion in the form of a triangular prism, and FIG. 9D includes a perspective view and a cross sectional view illustrating further still another embodiment of the separately produced bridge portion in the form of a semi-cylindrical shape;

FIG. 10A is a photograph showing the side view of a semiconductor light emitting apparatus of an exemplary embodiment just after the bridge portion has been formed, and FIG. 10B is a photograph showing the side view of the semiconductor light emitting apparatus just after the formation of the wavelength conversion layer;

FIG. 11 is a side view of a semiconductor light emitting apparatus of Comparative Example 2;

FIG. 12 is a graph showing the luminous intensity distribution along the lateral direction of the semiconductor light emitting apparatus of an exemplary embodiment (in the direction along which the elements are arranged);

FIG. 13 is a graph showing the luminous intensity distribution along the lateral direction of the semiconductor light emitting apparatus of Comparative Example 1 (in the direction along which the elements are arranged); and

FIG. 14 is a graph showing the luminous intensity distribution along the lateral direction of the semiconductor light emitting apparatus of Comparative Example 2 (in the direction along which the elements are arranged).

### DESCRIPTION OF EXEMPLARY EMBODIMENTS

A description will now be made below to semiconductor light emitting apparatuses of the presently disclosed subject matter with reference to the accompanying drawings in accordance with exemplary embodiments.

It should be noted that the present exemplary embodiments will deal with, as non-limiting examples, the cases of white light emitting apparatuses where a plurality of blue light emitting elements (blue LEDs) are arranged in line and a wavelength conversion layer containing a phosphor as a wavelength conversion material are used in combination. Herein, the phosphor can wavelength convert blue light which acts as an excitation light to yellowish orange light that is to be emitted, thereby producing white light by the mixture of blue light and yellowish orange light. It should be noted that the color combination and the color of the finally emitted light are not limited to the following exemplary embodiments, and the presently disclosed subject matter can employ various combinations of color achieved by various combinations of semiconductor light emitting elements and wavelength conversion materials.

It should also be noted that the main emission direction of light is defined as an upper direction or front direction, and based on this the down and horizontal directions and so on are defined accordingly.

### First Exemplary Embodiment

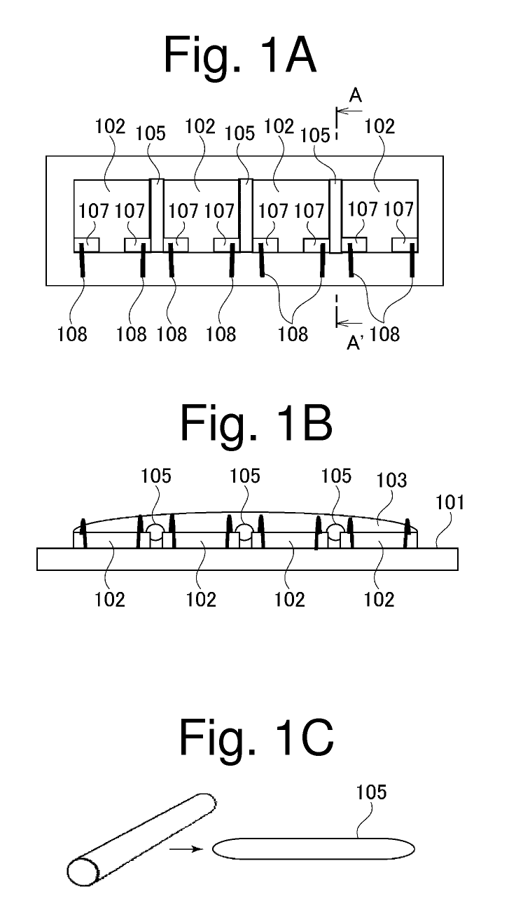

FIGS. 1A and 1B illustrate a semiconductor light emitting apparatus of a first exemplary embodiment, FIG. 1A being a top plan view of the semiconductor light emitting apparatus and FIG. 1B being a side view thereof. The semiconductor light emitting apparatus of the first exemplary embodiment can have four light emitting elements (LED chips) 102 disposed on a single substrate 101 at a predetermined gap interposed between the adjacent light emitting elements. Bridge portions 105 can be disposed between the adjacent light emitting elements 102 so that the corresponding gaps are covered therewith. Furthermore, a wavelength conversion layer 103 can cover the entire top surfaces of the four light emitting elements 102 and the bridge portions 105.

Each of the four light emitting elements 102 can be formed of an LED chip having a top surface as a light emitting surface for emitting blue light in the front direction (upward direction). The wavelength conversion layer 103 can be formed of a resin layer in which phosphor particles as a wavelength conversion material are dispersed. The phosphor particles can wavelength convert blue light as excitation light to emit yellowish orange fluorescence light. The phosphor particles can be YAG type phosphor particles as an example. The light emitting element 102 can have electrodes (wire bonding pads) 107 formed on the top surface. The four light emitting elements 102 can be disposed so that the electrodes 107 having the same polarity face upward. Then, the electrodes 107 can be wire bonded on the substrate 101 by bonding wires 108. Not-shown paired electrodes with respect to the electrodes 107 on the top surface can be formed on the other surfaces of the four light emitting elements 102. The paired electrodes can be electrically connected to an electrode pattern formed on the substrate 101. The wavelength conversion layer 103 can be disposed so that the electrodes 107 and the bonding wires 108 can be embedded therein in part.

The four light emitting elements 102 can emit blue light in the front direction (upper direction) and then the blue light can pass through the wavelength conversion layer 103 provided on the top surfaces of the elements. Part of the blue light can excite the phosphor contained in the wavelength conversion layer 103 so that the phosphor can emit yellowish orange fluorescence light. The blue light having passed through the wavelength conversion layer 103 and the generated yellowish orange fluorescence light can be mixed together so that white light can be projected from the wavelength conversion layer 103 upward.

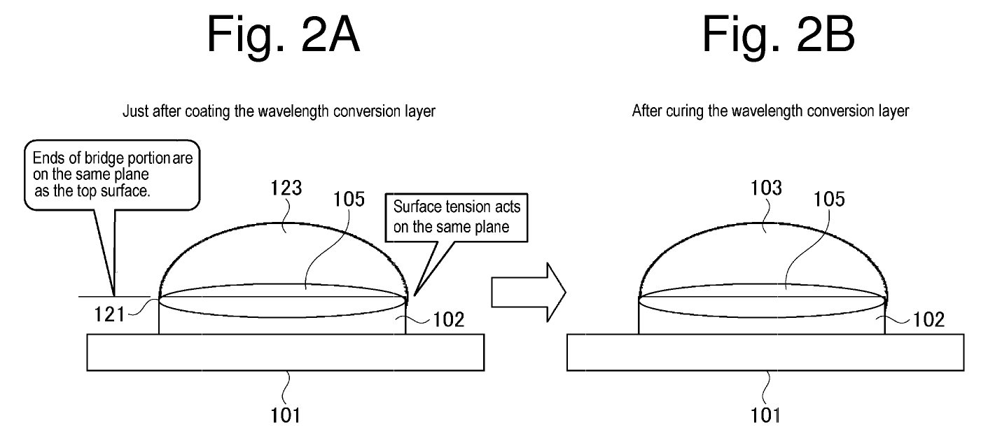

The wavelength conversion layer 103 can have a thickness as shown in FIGS. 1B and 2B. The thickness is decreased at least around the peripheral area to be the minimum at both the ends while it is increased toward the center area. In particular, the wavelength conversion layer 103 can have a shape without any end surface perpendicular to the main plane (or the top surface of the element 102). In other words, the wavelength conversion layer 103 can cover the connected four light emitting elements and can have the thickness being substantially zero at the outer peripheral area of the top surface. In this case, emission of light from the wavelength conversion layer 103 in the lateral direction or toward the substrate 101 can be prevented. In the conventional art, light can be emitted from the end surface of the wavelength conversion layer. Such light can be reflected by its surroundings to its front direction, thereby blurring the front luminous intensity distribution at the interface between the light emitting area and the surrounding non-light emitting area (outer environment). The configuration of the presently disclosed subject matter, however, can prevent such light from being emitted toward its surroundings, thereby achieving the sharp difference of front (top face) luminous intensity distribution between the light emitting area and the surrounding non-light emitting area (outer environment). Furthermore, as the wavelength conversion layer 103 has its thickness decreased toward the peripheral area, the light emitted from the wavelength conversion layer 103 can be directed upward in the front direction, thereby enhancing the sharp difference of the front luminous intensity distribution between the light emitting area and the surrounding non-light emitting area.

In the present exemplary embodiment, the top surface of the wavelength conversion layer 103 can be formed in a convex curved surface in the front direction. Accordingly, the wavelength conversion layer 103 can have a continuous curved surface from the center to the ends covering the connected light emitting elements 102 entirely. In other words, the wavelength conversion layer 103 can avoid having any end faces perpendicular to the main plane, and can have a continuously variable thickness from the center toward both the ends with the center portion being a topmost (i.e., apex) portion. This configuration can prevent light emitted from the wavelength conversion layer 103 from being directed laterally or toward the substrate 101. The light emitted from the wavelength conversion layer 103 upward can be controlled to show the luminous intensity distribution being flattened at the positions of the LED elements.

It should be noted that the thickness of the wavelength conversion layer 103 does not need to be decreased (e.g., tapered) in its entirety, but can be decreased (e.g., tapered) at least around the peripheral area of the wavelength layer 103. Accordingly, the surface of the wavelength conversion layer 103 at the center area may be completely flat (e.g., parallel to the top surface of the light emitting element).

The wavelength conversion layer 103 can be formed as a single layer over the four light emitting elements 102. When compared with the case where the four light emitting elements 102 each have the wavelength conversion layer 103, the wavelength conversion layer 103 can have a phosphor particle distribution with less localization of the phosphor particles, thereby preventing the light color unevenness and the luminous intensity unevenness.

The wavelength conversion layer 103 can be formed as a single layer over the entire surface of the connected four light emitting elements 102. As a result, the upper surface of the wavelength conversion layer 103 can be rectangular with four corners. In contrast, if the four light emitting elements 102 each have a wavelength conversion layer, the number of corners is 16 (4 by 4). Accordingly, the configuration of the presently disclosed subject matter can reduce the number of corners. When the thickness of a wavelength conversion layer is decreased (e.g., tapered) at the peripheral areas and also at the corners, the light emitted there can have a bluish white color because of a reduced amount of phosphor existing there. The configuration of the presently disclosed subject matter can employ the single wavelength conversion layer for covering the four light emitting elements 102 entirely, and the number of corners can be reduced, thereby suppressing the light color unevenness.

The method for forming the wavelength conversion layer 103 with such a shape is not specifically limited, and any method(s) suitable for this purpose can be employed. One method used for the present exemplary embodiment can include preparing a mixed liquid material for the wavelength conversion layer 103, dropping the mixed liquid material onto the four light emitting elements 102 connected via the bridge portions 105 while keeping its convex shape due to the surface tension, and curing it as it is. As a result, the wavelength conversion layer 103 can be easily formed with a shape of having a gradually decreasing thickness toward the peripheral areas.

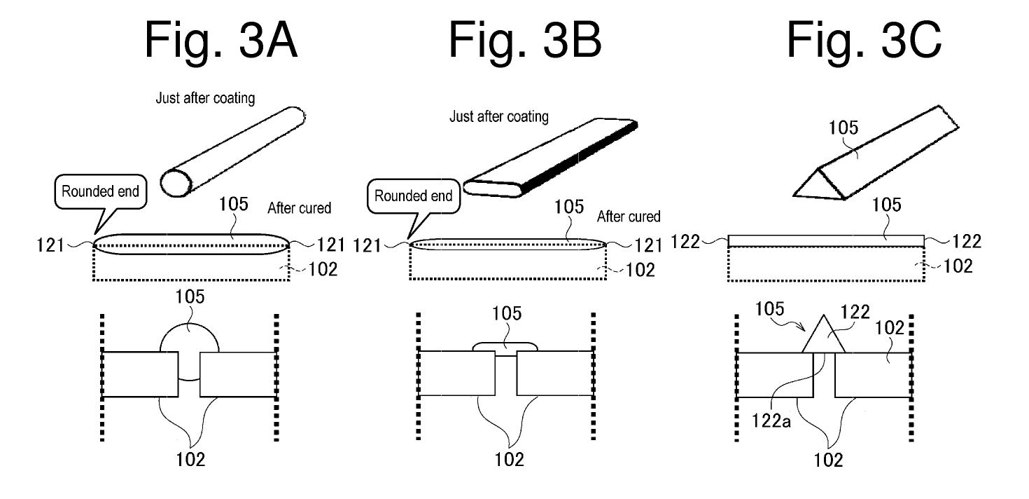

In order to form the wavelength conversion layer 103 utilizing the surface tension of the mixed liquid material, the bridge portion 105 can be shaped to have certain end shapes by maintaining the surface tension of the mixed liquid material on the bridge portions 105 after it has been dropped onto the light emitting elements 102. For example, the bridge portion 105 can have a circular cross section as shown in FIGS. 1C and 3A and the ends 121 in the lengthwise direction can be rounded so that the bridge portion 105 does not have any sharp end surface. Accordingly, as shown in FIG. 2A, the tips of the ends 121 can be disposed on the same plane as the top surface of the ends of the light emitting elements 102. In an alternative exemplary embodiment, the end 121 can be rounded to have an elliptic cross section as shown in FIG. 3B. This type of the bridge portion 105, can be disposed in the same manner as is the bridge portion 105 having the circular cross section. In another alternative exemplary embodiment, the bridge portion 105 can have an end face 122 triangular in shape as shown in FIG. 3C or rectangular in shape (being a triangular prism or rectangular prism). In this case, the bottom side 122a of the end face 122 (side near the substrate 101) can be configured to be disposed on the same plane as the top surface of the light emitting element 102. By doing so, when dropping the mixed liquid material for the wavelength conversion layer 103, the surface tension acting at the same points can be generated at the end of the light emitting element 102 and the end of the bridge portion 105. Accordingly, the convex shape of the mixed material liquid can be kept due to the surface tension across the four light emitting elements 102 connected via the bridge portions 105.

After the convex shape of the mixed liquid material is completed, the coating film 123 of the mixed liquid material can be formed as shown in FIG. 2A. The formed coating film 123 can be cured to form the domed wavelength conversion layer 103 with the thickness being continuously varied as shown in FIG. 2B and without a perpendicular end surface.

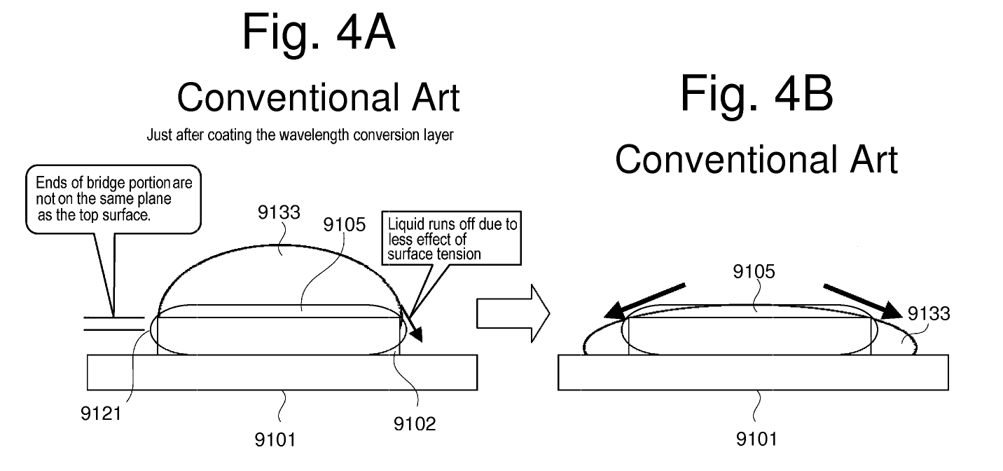

In contrast, as shown in FIG. 4A, if the ends 9121 of the bridge portion 9105 is positioned below the top surface of the end of the light emitting element 9102 so that the ends 9121 are not disposed on the same plane as the top surface of the light emitting element 9102, the surface tension acting on the ends of the light emitting element 9102 cannot be kept at the ends of the bridge portion 9105. Although the mixed liquid material 133 dropped onto the light emitting element 9102 can be shaped into a convex surface due to the surface tension on the light emitting element 9102, the surface tension cannot be kept at the ends of the bridge portion 9105. As a result, the mixed liquid material 9133 may run off from the ends of the bridge portion 9105 onto the substrate 9101, as shown in FIG. 4B. Accordingly, any stable coating film of the mixed liquid material cannot be formed.

The shape of the bridge portion 105 is not limited to the shapes shown in FIGS. 3A, 3B and 3C, and any shape that can keep the generated surface tension of the dropped mixed liquid material at its ends can be used.

The method for producing the bridge portion 105 can be a method of disposing a separately prepared member at an appropriate position, a method of directly coating a material between the light emitting elements 102, or other methods. In the exemplary embodiment, a method of coating or printing a resin material for the bridge portion directly between the light emitting elements 102 while the resin material is controlled in fluidity can be used. This method can form the bridge portion 105 with its ends 121 or bottom sides 122a of the end surfaces 122 being disposed on the same plane as the top surface of the ends of the light emitting element 102. Examples of the method for forming the bridge portion 105 can include, but are not limited to, a dispenser coating process, a screen printing process, a stencil printing process, and the like.

A description will now be made to the method for manufacturing a semiconductor light emitting apparatus of the present exemplary embodiment. Herein, the shape of the bridge portion 105 is exemplified as to have a circular cross section and rounded ends 121 as shown in FIGS. 1C and 3A.

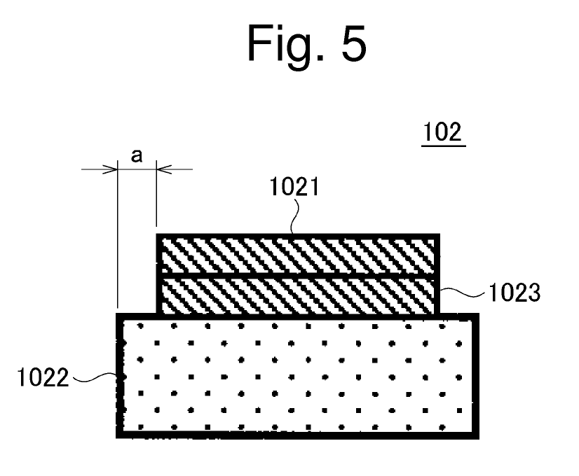

The light emitting elements 102 can be prepared in advance, as illustrated in FIG. 5. The light emitting element 102 can have a structure in which a thin semiconductor light emitting layer 1021 having a thickness of several microns is formed on a conductive opaque substrate 1022 such as a silicon or germanium substrate. A reflective layer 1023 such as silver or aluminum can be disposed between the light emitting layer 1021 and the opaque substrate 1022 so that almost all the light emitted from the light emitting layer 1021 can be projected in the front direction (upward) of the element. This type of light emitting element 102 can have a front light projection density to enhance its luminous intensity when compared with the case where a semiconductor light emitting layer is provided on a transparent sapphire substrate which is generally used.

The thin film semiconductor light emitting layer 1021 can be formed to have a smaller size than the conductor opaque substrate 1022. This is because, when the light emitting elements 102 are separated from a wafer including a plurality of elements 102 by dicing or scribing, the cleavage of the semiconductor light emitting layer 1021 and the associated damage at the interface can be prevented. Accordingly, a non-emission portion with a constant width “a” can exist on the top surface of the substrate 1022 and around the outer peripheral area of the light emitting layer 1021 as shown in FIG. 5.

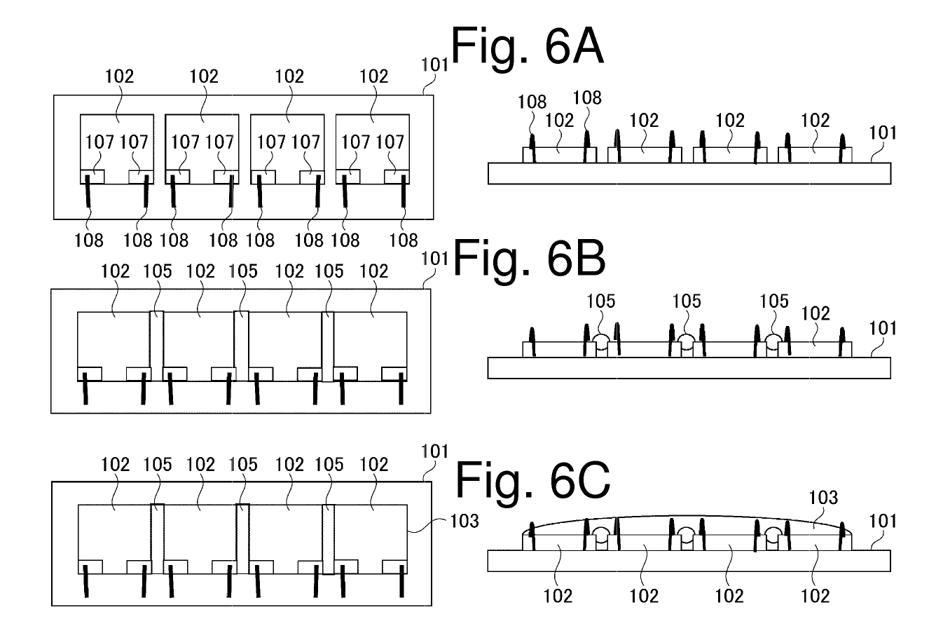

The substrate 101 may be a ceramic substrate having an electrode wiring pattern formed in advance on its surface. As shown in FIG. 6A, four light emitting elements 102 can be disposed in line with a predetermined gap interposed therewith on the substrate 101. Not shown common bonding material can be used for fixing the elements 102 on mounting areas of the substrate 101. Then, the electrodes 107 on the top surfaces of the light emitting elements 102 can be bonded to the electrodes of the ceramic substrate 101 by gold wire 108 or the like, thereby electrically connecting the electrode wiring pattern of the substrate 101 to the light emitting elements 102.

Then, the bridge portions 105 can be formed between the light emitting elements 102. The material for the bridge portion 105 can be selected from materials having heat resistance and stress resistance, such as, but not limited to, thermosetting resins, RTV rubbers, and the like. The bridge portion 105 can be formed so as to linearly fit the gap between the adjacent light emitting elements 102, thereby allowing the entire side surfaces of the four light emitting elements 102 to be continuous. Examples of the thermosetting resins for use as the material for the bridge portion 105 can include, but are not limited to, silicone resins, epoxy resins, phenol resins, polyimide resins, melamine resins, and the like. In addition, the resin material can be mixed with a filler such as, but not limited to, titanium oxide, alumina, or the like to impart a light reflecting property to the bridge portion 105. This can enhance the light utilization efficiency.

When employing a thermosetting resin, the bridge portion 105 can be formed by a dispenser coating process, a screen printing process or a stencil printing process. When it is formed by a dispenser coating process, the wire bonding process can be carried out before the formation of the bridge portion 105. This method can allow the wire bonding to be performed before the thermosetting resin material for the bridge portion 105 adheres to the electrode (wire bonding pad) 107. This can eliminate a need for a masking and the like for the electrode 107. Furthermore, this can improve the reliability of the bonding portions.

On the other hand, when it is formed by a screen or stencil printing process, a mask alignment process for printing can be taken into consideration and the wire bonding process can be performed before the formation of the bridge portion. The printing process can be carried out while the thermosetting resin material for the bridge portion 105 is prevented from adhering to the electrode 107. Depending on the position of the electrode 107, the bridge portion formation process and the wire bonding process can be performed in any arbitrary order.

The width of the bridge portion 105 can be adjusted to be wider than the gap between the adjacent light emitting elements 102 and smaller than the gap between the elements 102 plus twice the width “a” of the non-emission portion of the element 102 (see FIG. 5). The width of the bridge portion 105 greater than the above range may be less effective because the bridge portion 105 may cover part of the light emitting layer 1021.

Furthermore, the bridge portion 105 can be formed so that the longitudinal ends 121 of the bridge portion 105 are disposed on the same plane as the top surface of the light emitting elements 102.

In order to form such a controlled end position and a width of the bridge portion 105, it may be necessary to control the fluidity of the resin material for the bridge portion 105. Specifically, the resin material can be mixed with a material for increasing the viscosity or imparting thixotropy (i.e., using thixotropic material, such as silica or alumina nano-particles), thereby allowing the resin material to have thixotropy for maintaining its shape for a long period of time after coating or printing. When the bridge portion 105 is formed by a dispenser coating process, a material having appropriate thixotropy can be extruded with the use of a nozzle having a predetermined diameter while the dropping amount is controlled. This process can provide a coating film having ends disposed at appropriate positions and having an advantageous width. Specifically, the bridge portion 105 can be formed as a cylindrical resin material coating as shown in FIGS. 1C and 3A. The resin material can have certain thixotropy and fluidity, and accordingly, the coating can be rounded at its ends of the cylinder spontaneously after standing for a certain period of time. The tip shape of the end can be rounded as shown in FIGS. 1C and 3A. While this state is being kept, the material can be cured to form the bridge portion 105 having the ends disposed at the appropriate positions and with the appropriate width.

Specifically, the nozzle diameter can be set to the value equal to or greater than the gap between the adjacent light emitting elements 102 and smaller than the gap between the elements 102 plus twice the width “a” of the non-emission portion of the element 102 (see FIG. 5). This configuration can provide the bridge portion 105 with the width within the predetermined range as described above.

As the bridge portion 105 is formed so that the ends coincide with the top surface of the elements 102, a space can be formed between the bridge portion 105 and the substrate 101 below the bridge portion 105 as shown in FIG. 2B.

Next, the wavelength conversion layer 103 can be formed (see FIG. 6C). For example, particles of a YAG type phosphor can be dispersed in a silicone resin material to form a mixed liquid material and the liquid can be dropped by a dispenser or the like. The ends 121 of the bridge portion 105 can be formed on the same plane as the top surface of the light emitting element 102. Accordingly, the generated surface tension can be kept at the periphery of the light emitting elements 102 and the ends of the bridge portion 105. Thus, the convex shape of the mixed material liquid can be formed as a coating film of FIG. 2A. In this case, the coating film can be a single rectangular film covering the four light emitting elements 102 and the bridge portions 105 entirely. Namely, the coating film can be continuous over the four light emitting elements 102 and the bridge portions 105. Because of this, the surface concavity and convexity of the coating film can be leveled and can have a curved shape in accordance with the coated amount. Furthermore, the coating film can be formed as a single film. This can realize the uniform phosphor concentration above the respective light emitting elements 102. In the state that the thus formed shape of the coating film is kept, the coating film can be cured to be formed into the wavelength conversion layer 103.

The wavelength conversion layer 103 can be formed without any end surface perpendicular to the main plane but has thinned peripheral areas. Accordingly, the semiconductor light emitting apparatus of the present exemplary embodiment can have a front luminous intensity distribution having a sharp difference between the light emitting area and the surrounding non-light emitting area. Furthermore, as the wavelength conversion layer 103 can be formed as a single layer as a whole, the phosphor concentration above the respective light emitting elements can be evened with less light color unevenness and luminous intensity unevenness. In addition to this, as the wavelength conversion layer 103 can be limited to four corners over the area of the four light emitting elements 102, the wavelength conversion layer 103 can be prevented from having light color unevenness and luminous intensity unevenness due to a lot of corners.

### Second Exemplary Embodiment

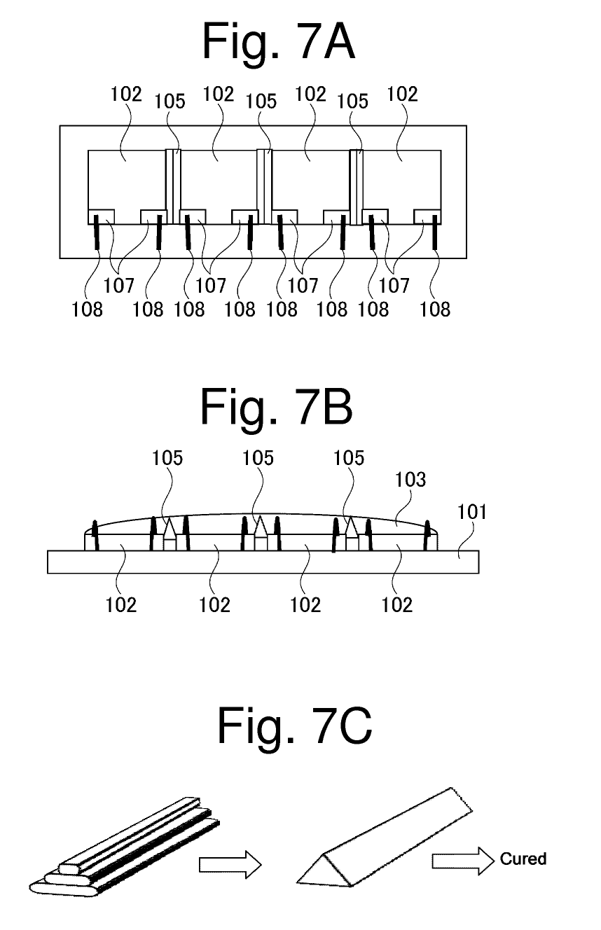

With reference to FIGS. 7A and 7B, a description will be made to a semiconductor light emitting apparatus of a second exemplary embodiment. The semiconductor light emitting apparatus of the present exemplary embodiment can have a bridge portion 105 having inclined surfaces along its longitudinal directions as shown in FIGS. 3C and 7A and 7B (for example, having an isosceles triangular cross section). The lower side of the ends of the bridge portion 105 can be formed to be disposed on the same plane as the top surface of the light emitting element so as to keep the surface tension of the coating film as in the first exemplary embodiment. The other configuration can be formed the same as the first exemplary embodiment.

The bridge portion 105 having the shape as shown in FIGS. 3C, 7A and 7B can be formed by a process of coating a resin material having thixotropic property with the use of a dispenser as in the first exemplary embodiment and repeating the process. Specifically, the opening of the nozzle of the dispenser may be elliptic to form an elliptic cylindrical resin material. Then, the extrusion pressure and other factors can be adjusted to control the extruded amount of the resin material and the coating is repeated while the major axis of the ellipse is gradually reduced so that the coating materials are overlaid at the same position, as shown in FIG. 7C. Accordingly, the laminate of elliptic cylindrical resin material layer can be formed. In this state, the formed laminate can stand for a predetermined period of time, thereby allowing the respective layers of the laminate to be fused and leveled, as shown in FIG. 7C. This can unite the laminate to form the resin material having an approximately triangular cross section.

The semiconductor light emitting apparatus of the present exemplary embodiment, the bridge portion 105 can have the inclined surfaces along its longitudinal direction as shown in FIG. 7B. These inclined surfaces intersect one another at a apex and can slope downward from the apex. Accordingly, even when the light emitted from the light emitting elements 102 is projected in the horizontally oblique directions, the light can be reflected by the inclined surfaces of the bridge portion 105, thereby allowing the light to be directed upward. This configuration can improve the front luminous intensity.

When the resin material for the bridge portion 105 includes a reflecting material (filler) mixed therein, it can be advantageous because the reflection effect can be improved. Examples of the reflecting material can include, but are not limited to, titanium oxide, alumina, and the like.

### Third Exemplary Embodiment

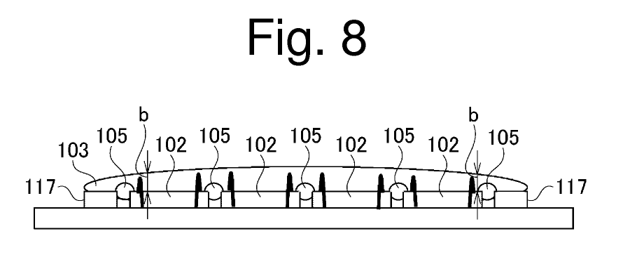

FIG. 8 is a side view illustrating the semiconductor light emitting apparatus of a third exemplary embodiment made in accordance with the principles of the presently disclosed subject matter. The semiconductor light emitting apparatus of FIG. 8 can include four light emitting elements 102 arranged in line and outermost pads 117 disposed on the respective outermost sides of the elements 102 in the arranged direction with a predetermined gap interposed therebetween. Another bridge portion 105 can be disposed between the outermost pad 117 and the light emitting element 102 adjacent to the pad 117. The remaining components and structure can be the same as those of the first exemplary embodiment.

When the wavelength conversion layer 103 is formed, the mixed liquid material can be coated over the entire surface covering the four light emitting elements 102 and the outermost pads 117 so that the convex shape of the coated liquid can be kept due to the generated surface tension. Accordingly, the single wavelength conversion layer 103 can be formed with the thickness “b” at the ends of the outermost light emitting elements 102 being thicker when compared with the case of no outermost pad 117. This means the difference in thickness of the wavelength conversion layer above the four light emitting elements can be reduced when compared with the case of no outermost pad 117. This configuration can thus reduce the light color unevenness occurring when the light is emitted through the wavelength conversion layer with different phosphor concentrations.

The height of the outermost pad 117 can be the same as that of the light emitting element 102. The ends and the outer peripheral areas of the light emitting elements 102 and the outermost pads 117 can be positioned on the same plane, so that the surface tension of the liquid material for the wavelength conversion layer can be kept. The width of the outermost pad 117 in the arranged direction can be equal to, or less than, the width of the light emitting element 102, and also can be equal to, or more than one half the width. If the width of the outermost pad 117 is less than one half of the width, it might not be possible to maintain the surface tension of the liquid for the wavelength conversion layer. If it is more than the width of the light emitting element, the entire size of the apparatus may be too large. The upper surface of the outermost pad 117 can be rectangular or semi-circular. A semi-circular shape with the linear side adjacent to the light emitting element 102 can keep the surface tension of the liquid for the wavelength conversion layer.

Materials of the outermost pad 117 can include, but are not limited to, a metal material, a ceramic material, a resin material or the like. Among them, metal with reflective silver plating or alumina can be advantageous in certain applications because the pad can reflect the light from the light emitting element upward (in the front direction).

As described above, a semiconductor light emitting apparatus made in accordance with the principles of the presently disclosed subject matter can include the bridge portions between the light emitting elements to connect the plurality of the light emitting elements, thereby facilitating the formation of the single wavelength conversion layer with a predetermined shape. Accordingly, it is possible to provide a light emitting apparatus with a novel light emission shape that is formed by connecting the elements in a unit.

It should be noted that the present exemplary embodiments have dealt with the cases in which the four light emitting elements are connected in line. The presently disclosed subject matter, however, is not limited to these exemplary embodiments. The light emitting elements can be arranged two by two, three by three, a letter L-shaped arrangement, a rectangular connected arrangement, or the like. In each of the embodiments the bridge portions can be formed between adjacent elements.

It should be noted that the present exemplary embodiments have dealt with the cases in which the bridge members are formed by arranging a thixotropic resin material between the adjacent light emitting elements 102 by a dispenser coating process or a printing process, and then curing the resin material. The presently disclosed subject matter, however, is not limited to these processes. For example, the bridge portions 105 can be separately produced to have a predetermined shape, and then the already produced bridge portions 105 can be mounted between the light emitting elements 102.

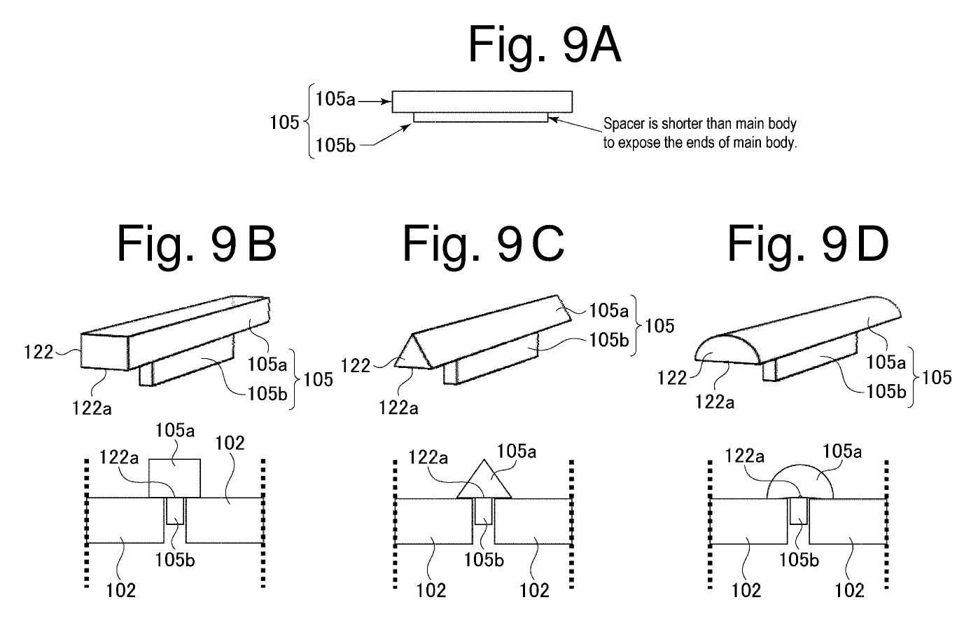

The bridge portions 105 can be produced by any suitable methods including, but not limited to, injection molding, laser processing, etching and the like. In this case, the bridge portion 105 can be produced to include a bridge main body 105a and a chip-insertion spacer 105b. The chip-insertion spacer 105b can support the bridge main body 105a and can be inserted into the predetermined gap between the light emitting elements 102. This configuration can ensure the fixing of the bridge portion 105. The length of the chip-insertion spacer 105b can be shorter than the main body 105a. Accordingly, there is no chip-insertion spacer just below the end surface 122 of the main body 105a so as to expose the bottom side 122a of the end surface 122. The shape of the bridge main body 105a can be any desired shape including, but not limited to, a rectangular prism, a triangular prism, a semi-cylindrical shape and the like, as shown in FIGS. 9B, 9C and 9D. The width of the bridge main body 105a can be set as in the previous exemplary embodiments. Specifically, it can be set at a value smaller than the predetermined gap between the elements 102 plus twice the width “a” of the non-emission portion of the element 102 (see FIG. 5). Accordingly, the bridge portion 105 of the present exemplary embodiment can be configured not to cover part of the light emitting layer 1021 (see FIG. 5).

As shown in FIGS. 9A to 9D, the bridge portion 105 can be produced in advance and then the chip-insertion spacer 105b can be inserted in between the light emitting elements 102. This configuration can fix the bridge portion 105 in the gap between the light emitting elements 102. Accordingly, the bottom side 122a of the end surface 122 of the bridge main body 105a can be positioned on the same plane as the top surface of the light emitting element 102 at its end. This configuration can keep the surface tension of the liquid material for the wavelength conversion layer so that the convex shape of the wavelength conversion layer can be ensured.

As described above, the effects of the semiconductor light emitting apparatus made in accordance with the principles of the presently disclosed subject matter can include:

(1) A plurality of light emitting elements that can be connected with the bridge portions disposed between the elements, and accordingly, a single wavelength conversion layer can be formed over them with a predetermined shape, thereby achieving the sharp difference of a front luminous intensity distribution between the light emitting area and the surrounding non-light emitting area (outer environment);

(2) A wavelength conversion layer can be formed in a continuous fashion over the light emitting elements, the surface concavity and convexity can be leveled during coating, meaning that the wavelength conversion layer can be shaped depending on the coating amount and the resulting layer can have a uniform phosphor concentration above the respective light emitting elements so that any light color unevenness and luminous intensity unevenness can be improved;

(3) The wavelength conversion layer can have a continuous surface by the provision of the bridge portions, and it is therefore possible to provide a light emitting apparatus with a novel light emission shape by the integrally formed wavelength conversion layer over the plurality of light emitting elements; and

(4) When the wavelength conversion layer is formed by a dispenser coating method, the wire bonding process can be performed before coating and masking for electrodes (wire bonding pads) may not be required, thereby preventing the electrode contamination and providing improved reliability.

The semiconductor light emitting apparatus of the present exemplary embodiments can be used as light sources for use in vehicle headlights, general lighting fixtures, street lamps, and various light emitting apparatuses.

### EXAMPLE

As an Example, the semiconductor light emitting element having the configuration as described with reference to FIGS. 7A and 7B was produced.

Specifically, a ceramic substrate 101 having a wiring pattern formed thereon in advance was prepared. Four light emitting elements 102 were arranged in line on the ceramic substrate 101, and were fixed with a bonding material. The gap between the adjacent light emitting elements 102 was one tenth of the width L of the light emitting element in the arranging direction. A resin material for the bridge portion 105 was prepared by mixing a silicone resin with 15% of silica fine particles (Aerosil 380 manufactured by Nippon Aerosil Co., Ltd.) for imparting thixotropy to the material, and dispersing titanium oxide particles having a particle size of 0.2 to 0.4 μm as a reflecting filler in the resin. This resin material was dropped in between the light emitting elements 102 while the dropped amount thereof was controlled with the use of a nozzle having an elliptic opening shape with an opening diameter of 0.05 mm×0.15 mm. Then, the resin material was heated at 150° C. for 120 minutes for curing. By doing so, the bridge portions 105 were formed so as to be disposed on the substantially same plane as the top surface of the element at its ends as shown in FIG. 2A and have inclined surfaces along its longitudinal direction with the shape of FIG. 7B.

Then, respective ends of the wires 108 were bonded to the electrodes (wire bonding pads) 107 and the wiring pattern on the substrate 101, respectively, for electrical connection therebetween.

A liquid material for the wavelength conversion layer 103 was prepared by mixing a silicone resin with YAG phosphor particles having a particle size of 15 μm (in an amount ratio of 23%). Then, a nozzle of a dispenser for the liquid material was scanned over the four light emitting elements 102 connected with the bridge portions 105 to drop the mixed liquid material over the four light emitting elements 102. The dropped mixed liquid material was configured to have a convex surface due to its surface tension so that a single coating film was formed to cover the four light emitting elements 102 entirely. The coating film was subjected to heat treatment at 50° C. for 90 minutes, and then again heat treatment at 150° C. for 120 minutes. As a result, the coating film was cured to complete the semiconductor light emitting apparatus of the present example.

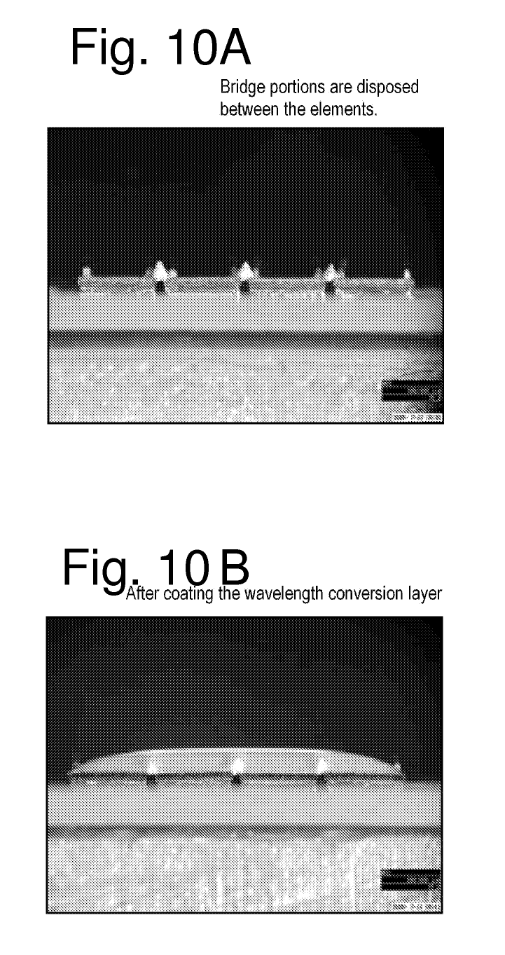

FIGS. 10A and 10B are photographs showing the side surface of the semiconductor light emitting apparatus of the present example. FIG. 10A is a photograph after the formation of the bridge portions 105 between the light emitting elements 102. As shown, the light emitting elements 102 are connected by the white resin (bridge portions 105). Furthermore, the photograph revealed that the bridge portion 105 had inclined surface on both sides.

FIG. 10B is a photograph after the wavelength conversion layer 103 covered the entire light emitting elements 102 connected. The photograph revealed that the wavelength conversion layer 103 had a convex curved surface near the center area due to the generated surface tension. Furthermore, the photograph revealed that both the ends of the layer 103 had reduced thicknesses so that any end surfaces were produced at both ends. Further, as shown, the wavelength conversion layer 103 had a symmetric shape.

As Comparative Example 1, another semiconductor light emitting apparatus was produced without a bridge portion 105 as used in the example above, and resin layers containing phosphor particles separately were formed on respective top surfaces of the light emitting elements 102 by printing instead of the single wavelength conversion layer 103. In Comparative Example 1, the semiconductor light emitting apparatus had one electrode 107 formed on its top surface. As the wavelength conversion layer provided by printing was formed on each light emitting element, when the elements were arranged, the independent four wavelength conversion layers were disposed at regular intervals in line. The formed wavelength conversion layer had a constant thickness due to the printing method employed, and it had end surfaces perpendicular to the top surface of the element.

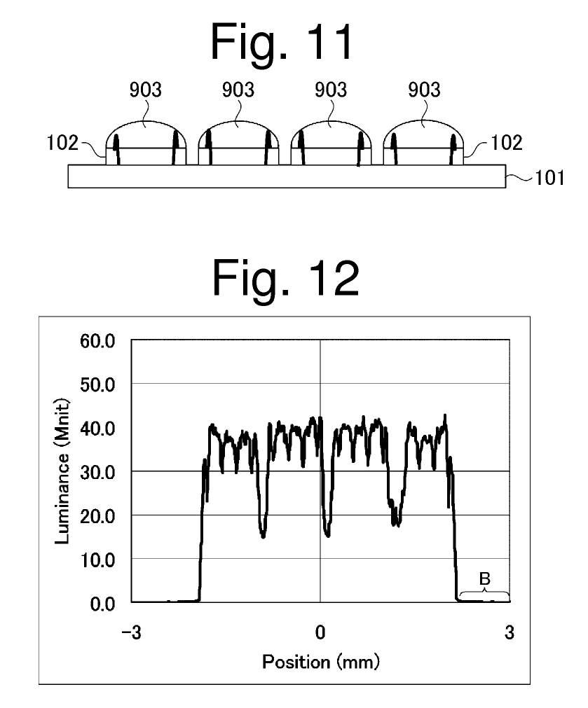

As Comparative Example 2, another semiconductor light emitting apparatus was produced as shown in FIG. 11. The semiconductor light emitting apparatus of the comparative example 2 had no bridge portion 105 as shown in the drawing. Furthermore, the semiconductor light emitting apparatus of Comparative Example 2 had domed wavelength conversion layers 903 on the respective top surfaces of the four light emitting elements 102 by dropping the same mixed material liquid (containing the resin and phosphor particles) as in the example onto the top surfaces, so as to provide a convex surface due to its surface tension, and curing the resin. The configuration of the light emitting element 102 itself was the same as the example of the presently disclosed subject matter.

FIGS. 12, 13 and 14 are graphs showing the cross-sectional luminous intensity distribution of each of the semiconductor light emitting apparatus of the Example and the Comparative Examples 1 and 2 (in the arranged line direction).

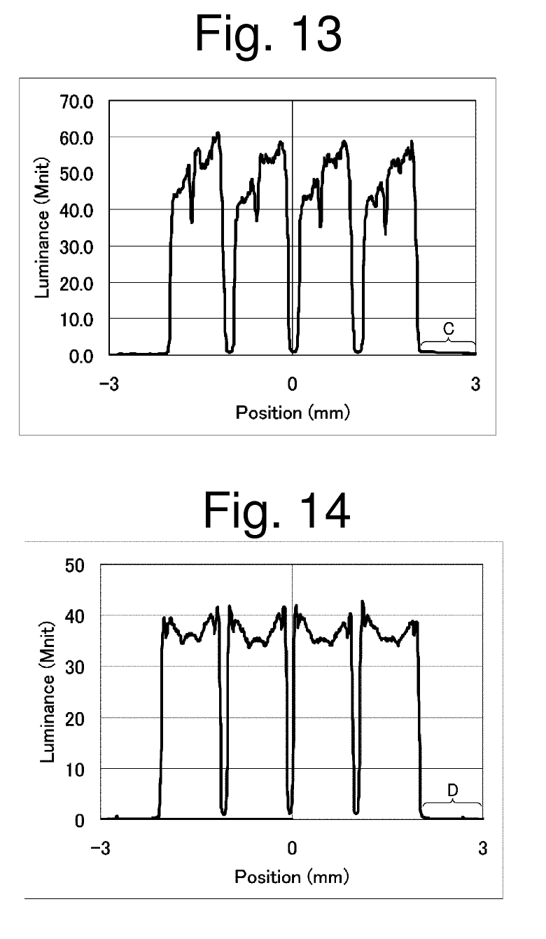

As shown in the luminous intensity distribution of the semiconductor light emitting apparatus of the Comparative Example 1 (FIG. 13), portions with low luminous intensity (valleys) exist between the light emitting elements. The luminous intensity at the valley was almost zero, so that the area does not project any light, meaning this portion was a dark portion. In the Comparative Example 1, the phosphor layer formed by printing had the perpendicular end surfaces. Accordingly, the luminous intensity distribution line at the non-light emission area C outside the elements was not flat (meaning the luminous intensity is zero) at all or substantially flat, but was inclined (meaning some light were observed there).

The semiconductor light emitting apparatus of Comparative Example 2 had independent domed phosphor layers 903 on the respective elements. Accordingly, the luminous intensity distribution of the semiconductor light emitting apparatus of Comparative Example 2 shown in FIG. 14 was flat at the non-light emission area D when compared with that at the non-light emission area C of Comparative Example 1. Furthermore, the difference between the light emission area and non-light emission area in the luminous intensity distribution line was sharp when compared with the case of Comparative Example 1. This means the improved effect could be obtain to some extent. However, as in Comparative Example 1, portions with low luminous intensity (valleys) exist between the positions of the light emitting elements. Accordingly, the luminous intensity at the valley was almost zero, so that the area does not project any light, meaning this portion was a dark portion. On the contrary, as shown in the luminous intensity distribution of the present example in FIG. 12, the reduction in the luminous intensity distribution between the light emitting elements could be suppressed by the single phosphor layer 103 covering the bridge portions 105 and the light emitting elements 102 entirely. The intensity obtained between the light emitting elements 102 can be half the maximum peak intensity or so. The single phosphor layer 103 had a domed shape covering the entire elements 102, so that the luminous intensity distribution of the semiconductor light emitting apparatus shown in FIG. 12 was flat at the non-light emission area D outside the emission area. Furthermore, it can be confirmed that the difference between the light emission area and non-light emission area in the luminous intensity distribution line was sharper than the case of comparative example 1.

It will be apparent to those skilled in the art that various modifications and variations can be made in the presently disclosed subject matter without departing from the spirit or scope of the presently disclosed subject matter. Thus, it is intended that the presently disclosed subject matter cover the modifications and variations of the presently disclosed subject matter provided they come within the scope of the appended claims and their equivalents. All related art references described above are hereby incorporated in their entirety by reference.

What is claimed is:

1. A semiconductor light emitting apparatus, comprising:
a substrate;
a plurality of light emitting elements each having a top surface configured as a light emitting surface and disposed on the substrate with a predetermined gap interposed between adjacent light emitting elements;
a plurality of bridge portions with each of the plurality of bridge portions disposed at a respective gap between the adjacent light emitting elements so as to connect the light emitting elements; and
a wavelength conversion layer disposed entirely over the top surfaces of the plurality of the light emitting elements and the bridge portions, the wavelength conversion layer having a decreased thickness at least around a peripheral area of the wavelength conversion layer and decreasing in thickness toward an end portion of the wavelength conversion layer.

2. The semiconductor light emitting apparatus according to claim 1, wherein the wavelength conversion layer has a top surface formed as a convex curved surface in a front direction.

3. The semiconductor light emitting apparatus according to claim 2, wherein the wavelength conversion layer is devoid of an end surface that is perpendicular to a main plane including the top surface of at least one of the light emitting elements.

4. The semiconductor light emitting apparatus according to claim 1, wherein the wavelength conversion layer includes a resin and a wavelength conversion material dispersed in the resin.

5. The semiconductor light emitting apparatus according to claim 2, wherein the wavelength conversion layer includes a resin and a wavelength conversion material dispersed in the resin.

6. The semiconductor light emitting apparatus according to claim 3, wherein the wavelength conversion layer includes a resin and a wavelength conversion material dispersed in the resin.

7. The semiconductor light emitting apparatus according to claim 1, wherein the predetermined gap has a length extending along a longitudinal axis of the predetermined gap and a width extending between the adjacent light emitting elements, and each of the plurality of bridge portions has a width and a length that are at least equal to the width and length of the predetermined gap between the adjacent light emitting elements, respectively, and the bridge portion has longitudinal ends that are coplanar with the top surface of at least one of the light emitting elements.

8. The semiconductor light emitting apparatus according to claim 2, wherein the predetermined gap has a length extending along a longitudinal axis of the predetermined gap and a width extending between the adjacent light emitting elements, and each of the plurality of bridge portions has a width and a length that are at least equal to the width and length of the predetermined gap between the adjacent light emitting elements, respectively, and the bridge portion has longitudinal ends that are coplanar with the top surface of at least one of the light emitting elements.

9. The semiconductor light emitting apparatus according to claim 3, wherein the predetermined gap has a length extending along a longitudinal axis of the predetermined gap and a width extending between the adjacent light emitting elements, and each of the plurality of bridge portions has a width and a length that are at least equal to the width and length of the predetermined gap between the adjacent light emitting elements, respectively, and the bridge portion has longitudinal ends that are coplanar with the top surface of at least one of the light emitting elements.

10. The semiconductor light emitting apparatus according to claim 4, wherein the predetermined gap has a length extending along a longitudinal axis of the predetermined gap and a width extending between the adjacent light emitting elements, and each of the plurality of bridge portions has a width and a length that are at least equal to the width and length of the predetermined gap between the adjacent light emitting elements, respectively, and the bridge portion has longitudinal ends that are coplanar with the top surface of at least one of the light emitting elements.

11. The semiconductor light emitting apparatus according to claim 1, wherein each of the plurality of bridge portions and the substrate define a vacant space therebetween.

12. The semiconductor light emitting apparatus according to claim 2, wherein each of the plurality of bridge portions and the substrate define a vacant space therebetween.

13. The semiconductor light emitting apparatus according to claim 3, wherein each of the plurality of bridge portions and the substrate define a vacant space therebetween.

14. The semiconductor light emitting apparatus according to claim 4, wherein each of the plurality of bridge portions and the substrate define a vacant space therebetween.

15. The semiconductor light emitting apparatus according to claim 1, wherein each of the plurality of bridge portions has a shape having an apex, a first surface inclined from the apex toward the top surface of a respective one of the plurality of light emitting elements, and a second surface inclined from the apex toward the top surface of the respective one of the plurality of light emitting elements, the first surface and second surface extending along a longitudinal direction of the gap.

16. The semiconductor light emitting apparatus according to claim 2, wherein each of the plurality of bridge portions has a shape having an apex, a first surface inclined from the apex toward the top surface of a respective one of the plurality of light emitting elements, and a second surface inclined from the apex toward the top surface of the respective one of the plurality of light emitting elements, the first surface and second surface extending along a longitudinal direction of the gap.

17. The semiconductor light emitting apparatus according to claim 3, wherein each of the plurality of bridge portions has a shape having an apex, a first surface inclined from the apex toward the top surface of a respective one of the plurality of light emitting elements, and a second surface inclined from the apex toward the top surface of the respective one of the plurality of light emitting elements, the first surface and second surface extending along a longitudinal direction of the gap.

18. The semiconductor light emitting apparatus according to claim 4, wherein each of the plurality of bridge portions has a shape having an apex, a first surface inclined from the apex toward the top surface of a respective one of the plurality of light emitting elements, and a second surface inclined from the apex toward the top surface of the respective one of the plurality of light emitting elements, the first surface and second surface extending along a longitudinal direction of the gap.

19. The semiconductor light emitting apparatus according to claim 1, wherein the bridge portion includes a resin and a filler located in the resin, the filler having a light reflecting property.

20. A method for producing a semiconductor light emitting apparatus, the method comprising:
providing a plurality of light emitting elements with each of the plurality of light emitting elements having a top surface configured as a light emitting surface;
disposing each of the plurality of light emitting elements on a substrate such that adjacent ones of the plurality of light emitting elements are spaced by a predetermined gap;
disposing each of a plurality of bridge portions at a respective one of the predetermined gaps located between the adjacent ones of the light emitting elements; and
forming a wavelength conversion layer entirely over the top surface of each of the plurality of the light emitting elements and over each of the bridge portions, and with a decreased thickness at least around a peripheral area of the wavelength conversion layer and decreasing in thickness toward an end portion of the wavelength conversion layer.

21. The method for producing a semiconductor light emitting apparatus according to claim 20, wherein the forming of the wavelength conversion layer comprises:
dropping a mixed liquid material for the wavelength conversion layer onto the plurality of bridge portions and the plurality of light emitting elements to form a coating film over all exposed surfaces of the bridge portions and light emitting elements such that the coating film forms a convex shape;
maintaining the convex shape by surface tension; and
curing the coating film.

22. The method for producing a semiconductor light emitting apparatus according to claim 21, wherein the disposing of the bridge portions comprises:
providing each of the plurality of bridge portions with a width and a length that are at least equal to a respective width and length of the predetermined gap between the adjacent light emitting elements; and
disposing the plurality of bridge portions so that longitudinal ends of the bridge portions are coplanar with the top surface of at least one of the light emitting elements.

23. The method for producing a semiconductor light emitting apparatus according to claim 22, wherein the disposing of the bridge portions comprises:
extruding a thixotropic resin material from a nozzle with a predetermined opening diameter so as to fill the predetermined gap between each of the light emitting elements therewith: and
curing the resin material.

24. The method for producing a semiconductor light emitting apparatus according to claim 23, wherein the disposing of the bridge portions comprises:
extruding a thixotropic resin material from a nozzle with a predetermined opening diameter so as to form the resin material disposed at the gap between the light emitting elements, such that the extruded material has an apex and surfaces inclined from the apex toward the top surface of at least one of the light emitting elements along the longitudinal direction of the gap; and
curing the resin material.

25. The method for producing a semiconductor light emitting apparatus according to claim 23, wherein the disposing of the bridge portions comprises disposing the thixotropic resin material only above the gap between the adjacent light emitting elements so as to define a vacant space between the substrate and the bridge portion.

26. The method for producing a semiconductor light emitting apparatus according to claim 20, further comprising, before the forming of a wavelength conversion layer, disposing wirings on the substrate, providing electrodes on the plurality of light emitting elements, and connecting the electrodes of the plurality of light emitting elements to the wirings formed by wire bonding.
